(19) United States
(12) Patent Application Publication
(10) Pub. No.: US 2025/0076425 A1
(43) Pub. Date: Mar. 6, 2025

(54) Coil Assembly, MRI System and Tuning Method

(71) Applicant: Siemens Healthineers AG, Forchheim (DE)

(72) Inventors: Tong Tong, Shenzhen (CN); Qiu Yi Zhang, Shenzhen (CN)

(73) Assignee: Siemens Healthineers AG, Forchheim (DE)

(21) Appl. No.: 18/817,683

(22) Filed: Aug. 28, 2024

(30) Foreign Application Priority Data
Aug. 29, 2023 (CN) 202311101304.2

(51) Int. Cl. G01R 33/34; G01R 33/36

(52) U.S. Cl. CPC G01R 33/34084; G01R 33/3628

(57) ABSTRACT

The present disclosure relates to a coil assembly, an MRI system, and a tuning method. The coil assembly comprises at least one stretchable RF receiving coil element, respectively comprising a variable capacitor, the variable capacitor being used to adjust a resonant frequency of the corresponding stretchable RF receiving coil element; and a tuning controller, at least configured to adjust a capacitance of the respective variable capacitor of the at least one stretchable RF receiving coil element, so that the resonant frequency of the at least one stretchable RF receiving coil element is within a preset range. The stretchable RF receiving coil element may be adjusted to a resonant state by means of a simple structure.

### CROSS-REFERENCE TO RELATED APPLICATIONS

The present application claims priority to and the benefit of China patent application no. CN 202311101304.2, filed on Aug. 29, 2023, the contents of which are incorporated herein by reference in their entirety.

### TECHNICAL FIELD

The present disclosure relates to the technical field of medical equipment and, in particular, to a coil assembly, a magnetic resonance imaging (MRI) system, and a tuning method.

### BACKGROUND

MRI is a technology in which the phenomenon of magnetic resonance is used to perform imaging. An MRI device transmits RF (radio frequency) pulses of a specific frequency toward a test subject in a static magnetic field by means of an RF coil to induce nuclear magnetic resonance of hydrogen protons in the body of the test subject for example, and receives magnetic resonance signals of the human body to acquire a magnetic resonance image of the inside of the human body.

In general, magnetic resonance signals generated by the human body are acquired using a receiving coil. During operation, the receiving coil may be positioned near the human body to receive magnetic resonance signals of a corresponding region of the test subject.

The method described in this section is not necessarily a previously envisaged or used method. Unless otherwise stated, it should not be assumed that any method described in this section is regarded as prior art simply because it is included in this section. Similarly, unless otherwise stated, problems mentioned in this section should not be regarded as having been generally acknowledged in any prior art.

### SUMMARY

A first aspect of the present disclosure includes a coil assembly comprising: at least one stretchable RF receiving coil element, respectively comprising a variable capacitor, the variable capacitor being used to adjust a resonant frequency of the corresponding stretchable RF receiving coil element; and a tuning controller, at least configured to adjust a capacitance of the respective variable capacitor of the at least one stretchable RF receiving coil element, so that the resonant frequency of the at least one stretchable RF receiving coil element is within a preset range.

A second aspect of the present disclosure includes an MRI system comprising the coil assembly described above.

A third aspect of the present disclosure includes a tuning method for the MRI system according to the second aspect above, the tuning method comprising: sending at least one first signal to at least one stretchable RF receiving coil element; receiving at least one second signal from the at least one stretchable RF receiving coil element, wherein the at least one second signal is a signal returned after the at least one first signal has respectively passed through a corresponding one of the at least one stretchable RF receiving coil element; and using a tuning controller to adjust a capacitance of a respective variable capacitor of the at least one stretchable RF receiving coil element according to the second signal, so as to adjust a resonant frequency of the at least one stretchable RF receiving coil element, until the resonant frequency of the at least one stretchable RF receiving coil element is adjusted to within a preset range.

According to embodiments of the present disclosure, providing the variable capacitor and tuning controller in the coil assembly enables the stretchable RF receiving coil element to be adjusted to a resonant state by means of a simple structure.

It should be understood that the content described in this section is not intended to limit the scope of the present disclosure. Other features of the present disclosure will become easy to understand through the following description.

### BRIEF DESCRIPTION OF THE DRAWINGS

Embodiments of the present disclosure are described in detail below with reference to the accompanying drawings, to give those skilled in the art a clearer understanding of the abovementioned and other features and advantages of the present disclosure. In the drawings:

FIG. 1 illustrates a schematic drawing of an example coil assembly in accordance with one or more embodiments of the present disclosure;

FIG. 2 illustrates a schematic drawing of an example coil assembly in one or more additional embodiments of the present disclosure;

FIG. 3 illustrates a schematic drawing of an example coil assembly in one or more further embodiments of the present disclosure;

FIG. 4 illustrates a functional block diagram of an example tuning controller according to one or more embodiments of the present disclosure;

FIG. 5A illustrates a schematic flow chart of an example tuning method for an MRI system according to one or more embodiments of the present disclosure; and

FIG. 5B illustrates a schematic flow chart of an example tuning method for an MRI system according to one or more embodiments of the present disclosure.

### KEY TO LABELS USED IN THE DRAWINGS

10 coil assembly;
100 stretchable RF receiving coil element;
102, 102a, 102b, 102n variable capacitor;
104, 104a, 104b, 104n directional coupler;
106, 106a, 106b, 106n first capacitor;
108, 108a, 108b, 108n second capacitor;
110, 110a, 110b, 110n low-noise amplifier (LNA) or low-noise converter (LNC);
112 stretchable conductor;
122 first signal;
124 second signal;
200 tuning controller;
30 magnetic resonance system;
40 body coil;
50 measurement reconstruction system;
310 first signal conversion module;
320 programmable logic module;
330 digital synthesis module;
340 second signal conversion module; and
126 control voltage.

### DETAILED DESCRIPTION OF THE DISCLOSURE

To enable a clearer understanding of the technical features, objectives, and effects of the present disclosure, embodiments of the present disclosure are explained with reference to the accompanying drawings, in which identical labels indicate identical parts.

An MRI system generally comprises a cavity-type magnet (e.g. a superconducting magnet) for providing a static magnetic field, cavity-type gradient coils inside the magnet, a cavity-type body coil inside the gradient coils, a bed body on which the test subject is placed, and a coil element for receiving magnetic resonance signals from the test subject.

The coil element may be constructed as a local coil arranged near the test subject. Examples are a spine coil mounted on a bed body of the MRI device; an abdomen coil or chest coil covering the test subject's abdomen or chest; and various other local coils covering particular regions of the test subject, such as a knee coil, shoulder coil, wrist coil, body array coil, head/neck coil, etc., for receiving magnetic resonance signals returned from the test subject. Specifically, the coil element may be excited in a tuned state to receive magnetic resonance signals from the test subject which are produced under excitation by high-frequency electromagnetic wave signals, or other high-frequency/RF electromagnetic wave signals returned by the test subject.

In addition to being used to receive magnetic resonance signals of corresponding regions of the test subject, coil elements such as abdomen coils, spine coils and chest coils may also be used to monitor certain important organs having physiological movement signals of periodic movement, such as the heart and lungs, due to being close to the corresponding regions of the test subject.

In recent years, there has been more and more research into coil elements, and stretchable, flexible conductors of coil elements in wearable coil devices are gradually becoming a focus of research in the MRI field. Research has found that in the process of being stretched, the inductance of the conductor will change considerably (for example, when liquid metal sealed in a silicone tube is used for testing, stretching by 10% will result in an increase of about 24 nH). At this time, if the capacitance in the coil element is kept unchanged, the resonant frequency of the coil element will change as the inductance of the conductor changes, thereby affecting the performance of the coil.

In view of the above, the present disclosure proposes a coil assembly containing a stretchable (e.g. flexible) RF receiving coil element. A variable capacitor and a tuning controller are provided in the coil assembly to adjust capacitance in the stretchable RF receiving coil element, so as to adjust a resonant state of the stretchable RF receiving coil element. Regardless of whether the coil is stretched, the capacitance and resonant frequency in the coil assembly according to embodiments of the present disclosure may be automatically tuned to a required value, thereby keeping the coil performance stable.

According to a first aspect of the present disclosure, a coil assembly 10 is provided. The coil assembly 10 comprises at least one stretchable RF receiving coil element 100 and a tuning controller 200. The at least one stretchable RF receiving coil element 100 respectively comprises a variable capacitor 102, the variable capacitor 102 being used to adjust a resonant frequency of the corresponding stretchable RF receiving coil element. The tuning controller 200 is at least configured to adjust the capacitance of the respective variable capacitor 102 of the at least one stretchable RF receiving coil element 100, so that the resonant frequency of the at least one stretchable RF receiving coil element 100 is within a preset range.

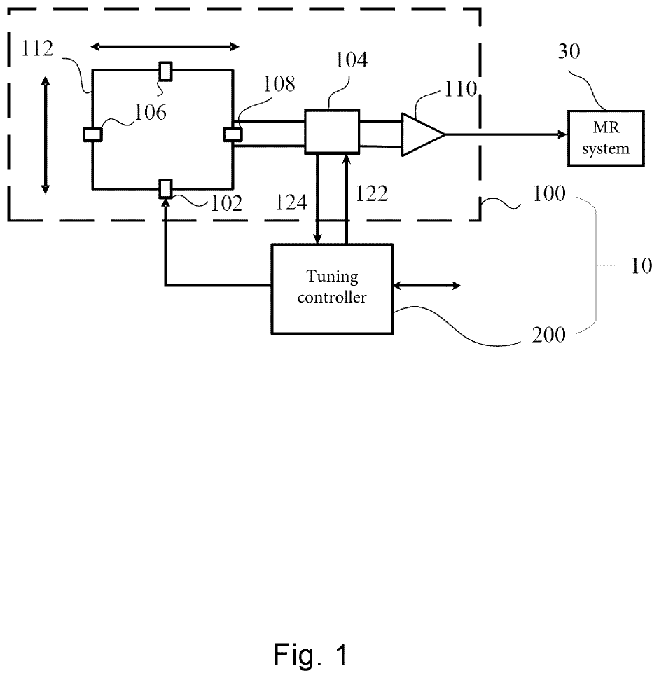

FIG. 1 shows a schematic drawing of a coil assembly according to an embodiment of the present disclosure.

In the embodiment shown in FIG. 1, the coil assembly 10 comprises one stretchable RF receiving coil element 100. The stretchable RF receiving coil element 100 comprises a capacitor circuit composed of multiple capacitors. The capacitor circuit comprises a first capacitor 106 and a second capacitor 108 connected in series. The first capacitor 106, shown as two capacitors in FIG. 1, may be a fixed-value capacitor, for causing the stretchable RF receiving coil element to resonate at a required magnetic resonance frequency. The second capacitor 108 may be a matching capacitor, for adjusting the matching of the stretchable RF receiving coil element 100, so that the stretchable RF receiving coil element 100 can receive magnetic resonance signals with maximum amplitude, so as to achieve better signal transmission. The stretchable RF receiving coil element 100 further comprises a low-noise amplifier (LNA) or a low-noise converter (LNC) 110, for performing low-noise amplification of magnetic resonance signals received by the stretchable RF receiving coil element 100 and transmitting the amplified signals to a magnetic resonance system 30 to undergo analog-to-digital conversion and digital reconstruction.

As indicated by the black double-ended arrows in FIG. 1, stretchable conductors 112 connecting the capacitors in the capacitor circuit can be stretched (e.g. flexed) in various directions. When the stretchable conductors 112 are in a stretched state, their inductance will increase, at which time, if the capacitance of each capacitor in the capacitor circuit remains unchanged, the resonant frequency of the stretchable RF receiving coil element 100 will change as the conductor inductance changes, thereby affecting the performance of the coil.

To solve this problem, the coil assembly 10 according to embodiments of the present disclosure comprises a variable capacitor 102 connected in series with the first capacitor 106 and the second capacitor 108, and a tuning controller 200. In some embodiments, the variable capacitor 102 may be a voltage-controlled capacitor. When the stretchable conductors 112 are in a stretched state, the tuning controller 200 is configured to adjust the capacitance of the variable capacitor 102 of the stretchable RF receiving coil element 100, so that the capacitance of the stretchable RF receiving coil element 100 in the stretched state is adjusted, thereby enabling the resonant frequency of the stretchable RF receiving coil element 100 to be within a preset range so that coil performance remains stable.

In some embodiments, the tuning controller 200 is further configured to transmit at least one first signal 122, the at least one first signal 122 being a signal having a magnetic resonance frequency, and the at least one stretchable RF receiving coil element 100 further comprises: a directional coupler 104, the directional coupler 104 being connected to the tuning controller 200, and used for transmitting to the at least one stretchable RF receiving coil element 100 the at least one first signal 122 transmitted by the tuning controller 200, and transmitting to the tuning controller 200 at least one second signal 124 returned by the at least one stretchable RF receiving coil element 100, wherein the at least one second signal 124 is a signal returned after the at least one first signal 122 has passed through one corresponding stretchable RF receiving coil element 100 of the at least one stretchable RF receiving coil element 100.

Continuing to refer to the embodiment shown in FIG. 1, the tuning controller 200 is further configured to transmit a first signal 122. In some embodiments, the first signal 122 is a test signal for example. The test signal may be generated by a small signal generator arranged in the tuning controller. The signal generator may be a direct digital frequency synthesizer (DDS) or a phase-locked frequency synthesizer (PLL), or a crystal oscillator having an analog output, for providing a test signal capable of operating at a magnetic resonance frequency.

The tuning controller 200 is further configured to receive a second signal 124. In the embodiment shown in FIG. 1, the second signal 124 is a signal returned after the first signal 122 has passed through the stretchable RF receiving coil element 100. By detecting the second signal 124 returned after passage through the stretchable RF receiving coil element 100, a tuning state of the stretchable RF receiving coil element 100 can be obtained.

The second signal 124 may for example be detected by means of an analog-to-digital converter (ADC) or a power detector. In some embodiments, to make tuning more precise, a transmitting component and a receiving component of the stretchable RF receiving coil element 100 may be calibrated during manufacture, and calibration data may be stored in the tuning controller. Since the stretchable RF receiving coil element's own parameters are calibrated and the calibration data is stored in the tuning controller, the stretchable RF receiving coil element's own parameters can be avoided when it is being adjusted, and thus tuning of the stretchable RF receiving coil element can be more accurate. In some embodiments, the tuning controller 200 is further configured to be in communicative connection with the magnetic resonance system 30 by means of a serial peripheral interface (SPI) or the I2C protocol.

Continuing to refer to the embodiment shown in FIG. 1, the stretchable RF receiving coil element 100 further comprises: the directional coupler 104, the directional coupler 104 being connected to the tuning controller 200 and used for transmitting to the stretchable RF receiving coil element 100 the first signal 122 transmitted by the tuning controller 200, and transmitting to the tuning controller 200 the second signal 124 returned by the stretchable RF receiving coil element 100, so as to realize signal transmission between the stretchable RF receiving coil element 100 and the tuning controller 200. The directional coupler 104 may be realized by a printed circuit board, or lumped elements such as an inductor and a capacitor.

In some embodiments, the tuning controller 200 is configured to determine whether to adjust the capacitance of the at least one variable capacitor 102 according to whether the at least one second signal 124 is within a threshold range.

The received second signal 124 is compared with a preset threshold range. If the second signal 124 is not within the preset threshold range, it is determined to adjust the capacitance of the variable capacitor 102. The tuning controller 200 is further configured to adjust a voltage applied across the variable capacitor 102 (e.g. voltage-controlled capacitor), so as to adjust the capacitance of the variable capacitor 102, until the returned second signal is determined to reach an expected value. If the second signal 124 is within the preset threshold range, it is determined to not adjust the capacitance of the variable capacitor 102.

In some embodiments, if the difference between the resonant frequency of the stretchable RF receiving coil element 100 and the preset threshold range does not exceed a predetermined threshold value, a fixed capacitor may be connected in parallel with the variable capacitor 102, so as to realize more precise adjustment.

In some embodiments, to save electricity and avoid interference to magnetic resonance images, the tuning controller 200 may be further configured to be set to an OFF state or a sleep state after completing tuning of the at least one stretchable RF receiving coil element.

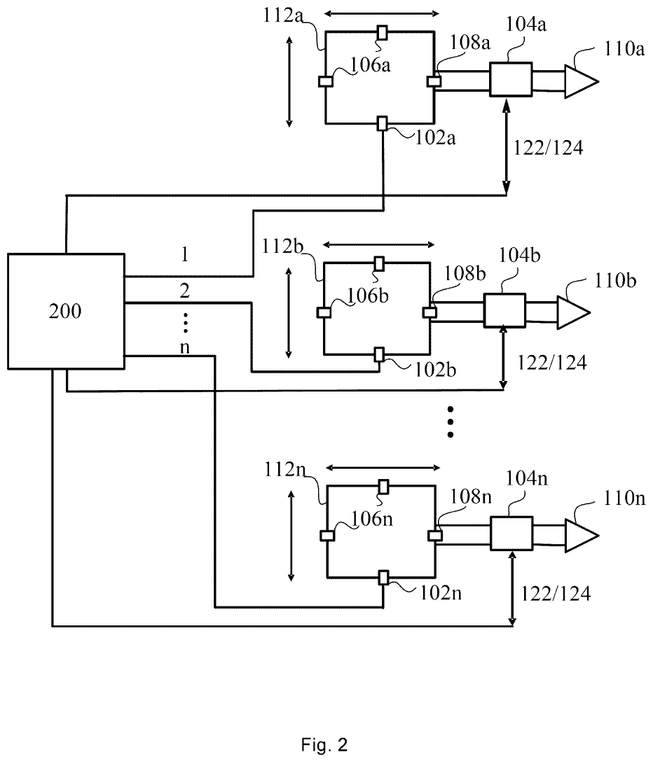

FIG. 2 shows a schematic drawing of a coil assembly according to an embodiment of the present disclosure.

In the embodiment shown in FIG. 2, the coil assembly 10 comprises multiple stretchable RF receiving coil elements 100. The multiple stretchable RF receiving coil elements respectively comprise corresponding variable capacitors 102a, 102b . . . 102n, the variable capacitors 102a, 102b . . . 102n being used to adjust resonant frequencies of the corresponding stretchable RF receiving coil elements. The tuning controller 200 is configured to adjust the capacitances of the respective variable capacitors 102a, 102b . . . 102n of the multiple stretchable RF receiving coil elements so that the resonant frequency of each of the multiple stretchable RF receiving coil elements is within a preset range.

Continuing to refer to FIG. 2, the tuning controller 200 is further configured to transmit a first signal 122 to each of the multiple stretchable RF receiving coil elements 100. The first signals 122 transmitted to the stretchable RF receiving coil elements 100 by the tuning controller 200 may be test signals having a magnetic resonance frequency, and the multiple first signals 122 may be the same or different; no restrictions are imposed here.

In the embodiment shown in FIG. 2, each of the multiple stretchable RF receiving coil elements 100 further comprises: a directional coupler 104a, 104b . . . 104n, the directional couplers 104a, 104b . . . 104n being connected to the tuning controller 200 and used for respectively transmitting, to each corresponding one of the multiple stretchable RF receiving coil elements 100, the multiple first signals transmitted by the tuning controller 200, and transmitting to the tuning controller 200 the second signal returned by each of the multiple stretchable RF receiving coil elements 100. Similar to the embodiment shown in FIG. 1, the second signal is a signal returned after the first signal has passed through the corresponding stretchable RF receiving coil element 100.

In the embodiment shown in FIG. 2, the tuning controller 200 is further configured to compare each of the multiple second signals received within a preset threshold range. If a second signal is not within the preset threshold range, it is determined to adjust the capacitance of the variable capacitor corresponding to this second signal. In this case, the tuning controller is further configured to adjust a voltage applied across the variable capacitor (e.g. a voltage-controlled capacitor) corresponding to this second signal, so as to adjust the capacitance of the variable capacitor corresponding to this second signal. If a second signal is within the preset threshold range, it is determined to not adjust the capacitance of the variable capacitor corresponding to this second signal.

It should be understood that in the embodiment shown in FIG. 2, the tuning controller 200 can adjust each of the multiple stretchable RF receiving coil elements 100. The tuning controller 200 can control a voltage value across the variable capacitor in any one of the stretchable RF receiving coil elements without being affected by the other stretchable RF receiving coil elements. Through the use of the tuning controller 200 to control at least one stretchable RF receiving coil element 100, the coil assembly according to the present disclosure can maximize the utilization rate of the tuning components and avoid redundancy.

In addition, the coil assembly according to the present disclosure can simplify the tuning process during production. A conventional coil assembly generally needs to have each coil tuned when the product leaves the factory, whereas the stretchable RF receiving coil element in the coil assembly according to the present disclosure only needs the voltage of the variable capacitor to be adjusted during use to realize tuning, so the step of tuning when leaving the factory is simplified. In contrast to a conventional tuning process required to be performed on a coil element, the stretchable RF receiving coil element in the coil assembly according to the present disclosure may also realize remote tuning.

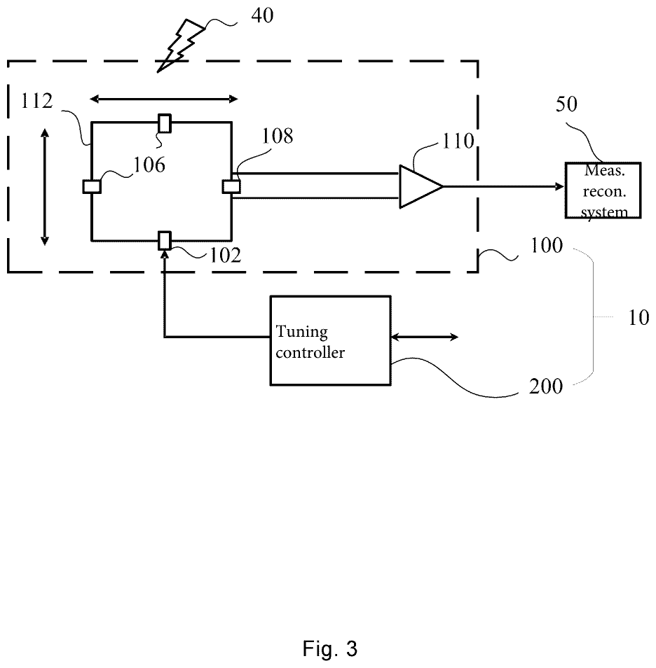

FIG. 3 shows a schematic drawing of a coil assembly according to another embodiment of the present disclosure.

Similar to the embodiment shown in FIG. 1, the coil assembly 10 comprises a stretchable RF receiving coil element 100. The stretchable RF receiving coil element 100 comprises a capacitor circuit composed of multiple capacitors, and a low-noise amplifier (LNA) or low-noise converter (LNC) 110.

Unlike the embodiment shown in FIG. 1, in the embodiment shown in FIG. 3, the first signal 122 (e.g. test signal) is not transmitted to the stretchable RF receiving coil element 100 by the tuning controller 200, but instead is transmitted to the stretchable RF receiving coil element 100 by another apparatus of the MRI system. The second signal 124 returned after passage through the stretchable RF receiving coil element 100 may also be received by another apparatus of the MRI system, and not be the tuning controller 200. In the embodiment shown in FIG. 3, the coil assembly 10 may not comprise the directional coupler 104.

The MRI system comprises a body coil 40 and a measurement reconstruction system 50. The body coil is generally an RF coil arranged inside a gradient coil, and used to generate a high-frequency magnetic field, and apply the high-frequency magnetic field to a test subject in a static magnetic field. The body coil has a large FOV (field of view) when a transmitted signal is uniform; therefore, if a local coil of the stretchable RF receiving coil element 100 for example is within the FOV of the body coil, the local coil can couple with the body coil. On this basis, in the embodiment shown in FIG. 3, the body coil 40 is used to provide a first signal, which may be a test signal for example. In addition, the measurement reconstruction system 50 in the MRI system may also be used to receive a second signal from the stretchable RF receiving coil element 100. The amplitude of the first signal may be set lower than a signal amplitude capable of activating passive detuning of the stretchable RF receiving coil element 100. Thus, when the body coil transmits a first signal of a radio frequency for example, it will not activate a passive detuning function of the stretchable RF receiving coil element 100 and thus cause the stretchable RF receiving coil element 100 to be in a detuned state. In this case, after setting each stretchable RF receiving coil element 100 in the local coil to a receiving state, the stretchable RF receiving coil element 100 can be tuned.

In some embodiments, the tuning controller 200 is in communicative connection with the measurement reconstruction system 50. In some embodiments, the measurement reconstruction system 50 may send the second signal to the tuning controller 200, and the tuning controller 200 determines whether to adjust the capacitance of the variable capacitor 102 according to whether the second signal is within a threshold range. In some embodiments, it is also possible for the measurement reconstruction system 50 to determine whether to adjust the capacitance of the variable capacitor 102 according to whether the second signal is within a threshold range, and send a corresponding instruction (such as a control signal) to the tuning controller 200. If the second signal is not within a preset threshold range, the tuning controller 200 is further configured to adjust a voltage applied across the variable capacitor 102 (e.g. voltage-controlled capacitor), so as to adjust the capacitance of the variable capacitor 102, until the returned second signal is determined to reach an expected value. If the second signal 124 is within the preset threshold range, it is determined to not adjust the capacitance of the variable capacitor 102.

Similar to the embodiment shown in FIG. 2, the coil assembly 10 in the embodiment of FIG. 3 according to the present disclosure may also comprise multiple stretchable RF receiving coil elements 100. Unlike the embodiment shown in FIG. 2, each of the multiple stretchable RF receiving coil elements 100 receives a first signal from the body coil 40. The measurement reconstruction system 50 can receive a returned second signal from each corresponding stretchable RF receiving coil element 100. The measurement reconstruction system 50 may send the second signal to the tuning controller 200, and the tuning controller 200 determines whether to adjust the capacitance of the corresponding variable capacitor 102 according to whether the second signal is within a threshold range. It is also possible for the measurement reconstruction system 50 to determine whether to adjust the capacitance of the corresponding variable capacitor 102 according to whether the second signal is within a threshold range, and send a corresponding instruction to the tuning controller 200.

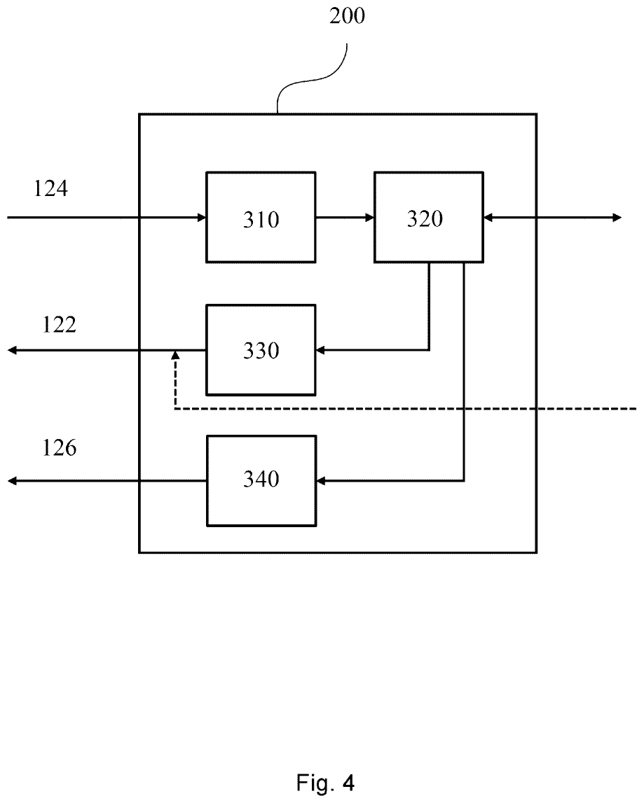

FIG. 4 shows a functional block diagram of a tuning controller 200; the tuning controller 200 may for example be applied in the embodiments shown in FIGS. 1-3.

According to some embodiments of the present disclosure, the tuning controller 200 may comprise a second signal conversion module 310, a control module (e.g. a programmable logic module) 320, a test signal generating module (digital synthesis module) 330, and a control voltage signal generating module 340.

The second signal conversion module 310 is configured to convert the received second signal 124 to a signal that can be transmitted by a digital circuit. The second signal conversion module 310 may be an analog-to-digital converter (ADC) or a power detector for example, and may be used to convert a received analog signal so that the converted signal can be transmitted by means of a digital circuit.

The control module (e.g. programmable logic module) 320 is configured to generate various control instructions, e.g. instructions indicating whether to generate a test signal, instructions indicating whether to adjust the capacitance of a variable capacitor, etc. The control module 320 may be a field programmable logic gate array (FPGA) or complex programmable logic device (CPLD) for example; the control module 320 may be in communicative connection with a system, and may be used for subjecting a digital signal or DC signal to computation and generating a corresponding instruction.

The test signal generating module 330 is configured to generate a first signal. The test signal generating module 330 may be a DDS signal generator or a phase-locked frequency synthesizer (PLL) for example, and is used for generating, on the basis of an instruction, an RF signal as a test signal for measuring a resonant frequency of a coil assembly.

The control voltage signal generating module 340 is configured to generate a signal for controlling the voltage of a variable capacitor. The control voltage signal generating module 340 may be a digital-to-analog converter (DAC) for example, and is used to provide a controllable DC voltage for a variable capacitor.

In some embodiments, after the second signal 124 has been transmitted to the tuning controller 200, the second signal 124 (which for example is a high-frequency signal) may be converted to a DC signal by means of the second signal conversion module 310, to undergo characterization. Next, the converted second signal 124 is subjected to computation in the programmable logic module 320, and based on comparison of a computation result with a preset threshold range, a determination is made as to whether to issue an instruction to adjust a voltage of a variable capacitor. The control module 320 may also be connected to an MRI system via a communication interface, for example I2C or SPI.

In some embodiments, for example in the embodiment shown in FIG. 1 or FIG. 2, the control module 320 in the tuning controller 200 may be configured to send an instruction to the test signal generating module 330, and the test signal generating module 330 generates a first signal 122 according to the instruction. In some embodiments, for example as indicated by the dotted arrow in FIG. 4, in the embodiment shown in FIG. 3 for example, the first signal 122 could also be generated by the MRI system directly, e.g. generated by a body coil and sent into the stretchable RF receiving coil element. That is to say, in the embodiment shown in FIG. 3 for example, the test signal generating module 330 is optional.

In some embodiments, the control module 320 in the tuning controller 200 may also be configured to send an instruction to the control voltage signal generating module 340, so as to generate a control voltage 126 for controlling a voltage across the variable capacitor 102.

According to a second aspect of the present disclosure, an MRI system is provided, comprising a coil assembly according to any one of the embodiments above.

It should be understood that the features and advantages described above in relation to the coil assembly are likewise applicable to the MRI system. For conciseness, some features and advantages are not described again here.

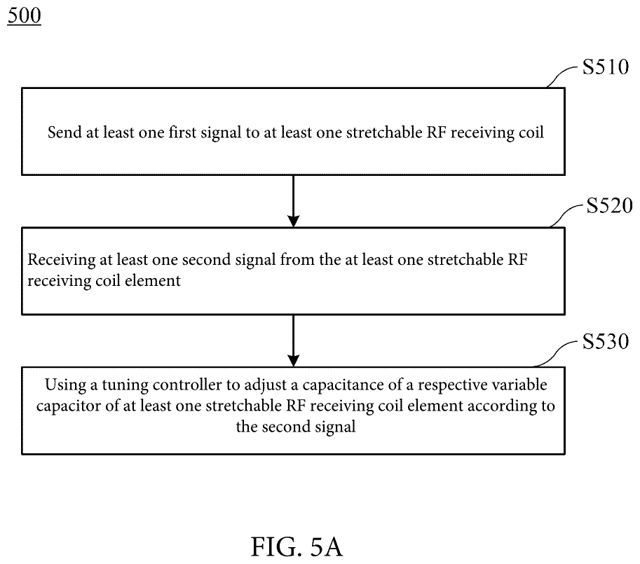

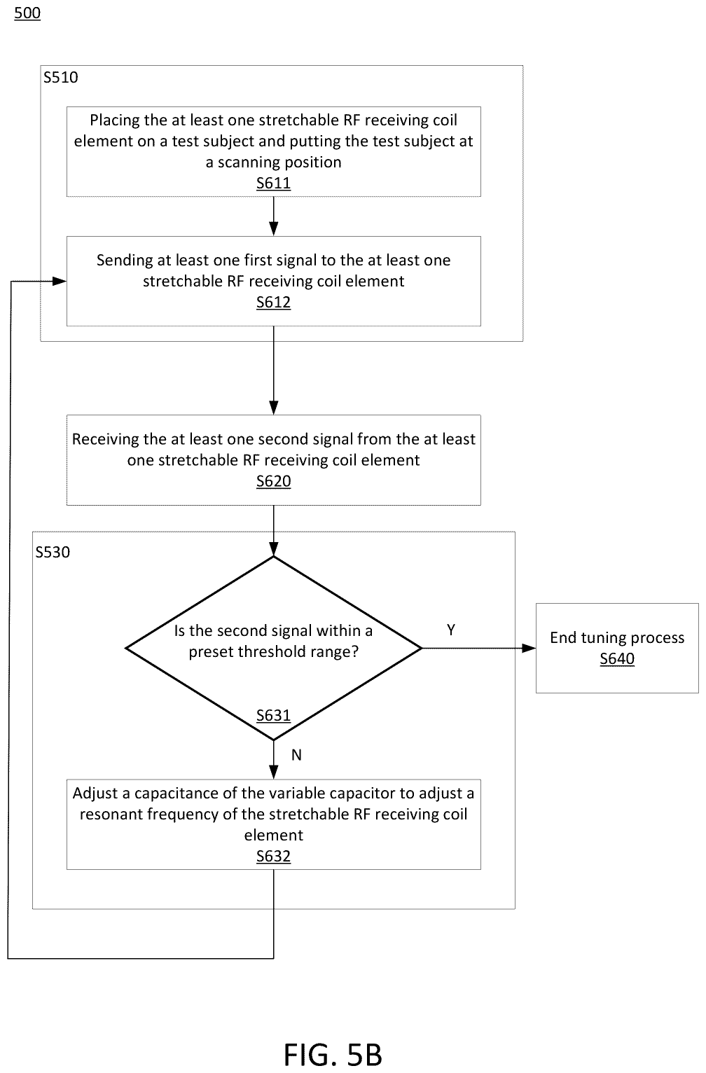

According to a third aspect of the present disclosure, a tuning method 500 is provided, for the MRI system according to the second aspect above. Referring to FIG. 5A, the method 500 comprises:
step S510, sending at least one first signal to at least one stretchable RF receiving coil element;
step S520, receiving at least one second signal from the at least one stretchable RF receiving coil element, wherein the at least one second signal is a signal returned after the at least one first signal has respectively passed through a corresponding one of the at least one stretchable RF receiving coil element; and
step S530, using a tuning controller to adjust a capacitance of a respective variable capacitor of at least one stretchable RF receiving coil element according to the second signal, so as to adjust a resonant frequency of the at least one stretchable RF receiving coil element, until the resonant frequency of the at least one stretchable RF receiving coil element is adjusted to within a preset range.

In some embodiments, for example in embodiments in which the tuning controller comprises the test signal generating module 330 and the second signal conversion module 310, the tuning controller may send at least one first signal and receive at least one second signal from at least one stretchable RF receiving coil element. Referring to FIG. 5B, step S510, sending at least one first signal to at least one stretchable RF receiving coil element, comprises:
step S611, placing the at least one stretchable RF receiving coil element on a test subject and putting the test subject at a scanning position; and
step S612, using the tuning controller to send at least one first signal to the at least one stretchable RF receiving coil element.

In some embodiments, in step S611, once the test subject has been placed on a bed body, the at least one stretchable RF receiving coil element according to embodiments of the present disclosure is placed on a region to be scanned of the test subject. Once the stretchable RF receiving coil element on the region to be scanned of the test subject has been fixed in place and the test subject has reached the scanning position, the method proceeds to step S612, using the tuning controller to send at least one first signal to the at least one stretchable RF receiving coil element.

In some embodiments, the method continues to step 620, using the tuning controller to receive the at least one second signal from the at least one stretchable RF receiving coil element, wherein the at least one second signal is a signal returned after the at least one first signal has respectively passed through a corresponding one of the at least one stretchable RF receiving coil element.

In some embodiments, the method continues to step S530, wherein step S530, using a tuning controller to adjust a capacitance of a respective variable capacitor of at least one stretchable RF receiving coil element according to the second signal, so as to adjust a resonant frequency of the at least one stretchable RF receiving coil element, until the resonant frequency of the at least one stretchable RF receiving coil element is adjusted to within a preset range, comprises:
step S631, using the tuning controller to determine, according to the at least one second signal, whether to adjust a capacitance of a respective variable capacitor of the at least one stretchable RF receiving coil element.

After receiving the second signal, the tuning controller may compare the obtained second signal with a preset threshold range.

If the second signal is within the preset threshold range, the process proceeds to step S640, in which the tuning process ends.

If the second signal is not within the preset threshold range, the process proceeds to step S632, using a tuning controller to adjust a capacitance of a respective variable capacitor of the at least one stretchable RF receiving coil element, so as to adjust a resonant frequency of the at least one stretchable RF receiving coil element. When adjustment of the resonant frequency of the at least one stretchable RF receiving coil element is complete, the process returns to step S612, using the tuning controller to send at least one first signal to the at least one stretchable RF receiving coil element. When the resonant frequency of the at least one stretchable RF receiving coil element 100 has been adjusted to within a preset range, i.e. when the returned second signal is within the preset threshold range, the tuning process ends.

At this time, the tuning controller 200 may be set to an OFF state or a sleep state.

In other embodiments, for example in embodiments in which the tuning controller does not comprise the test signal generating module 330 and the second signal conversion module 310, a body coil of the MRI system may transmit a first signal, and a measurement reconstruction system receives a second signal returned by means of a stretchable RF receiving coil element, processes the second signal if necessary, and based on the second signal, issues an instruction indicating whether to adjust a variable capacitor of the stretchable RF receiving coil element. In this case, the method 500 may comprise: using a tuning controller to receive from a measurement reconstruction system a second signal or a control instruction issued by the measurement reconstruction system and indicating whether to adjust a variable capacitor of a stretchable RF receiving coil element, and adjusting a capacitance of a respective variable capacitor of the at least one stretchable RF receiving coil element according to the received second signal or control instruction, until a resonant frequency of the at least one stretchable RF receiving coil element is adjusted to within a preset range.

Although embodiments or examples of the present disclosure have already been described with reference to the drawings, it should be understood that the abovementioned methods, systems and devices are merely exemplary embodiments or examples, and the scope of the present invention is not limited by these embodiments or examples, instead being defined solely by the granted claims and the equivalent scope thereof. Various key elements in the embodiments or examples may be omitted or may be replaced by equivalent key elements thereof. In addition, the steps may be executed in an order different from that described in the present disclosure. Furthermore, various key elements in the embodiments or examples may be combined in various ways. Importantly, as technology evolves, many key elements described here may be replaced by equivalent key elements appearing after the present disclosure.

As used herein, “schematic” means “serving as an instance, example, or illustration”. No drawing or embodiment described herein as “schematic” should be interpreted as a more preferred or more advantageous technical solution.

In the present disclosure, unless otherwise stated, the use of the terms “first”, “second” etc. to describe various key elements is not intended to define a positional relationship, time sequence relationship or importance relationship between these key elements; such terms are merely used to distinguish one element from another. In some examples, a first key element and a second key element may refer to the same instance of the element in question, whereas in some cases, based on the description in the context, they may also denote different instances.

Terms used in the descriptions of the various examples in the present disclosure are intended to describe specific examples, and are not intended to impose restrictions. Unless clearly indicated otherwise in the context, if the quantity of a key element is not specifically defined, the key element may be one or more. In addition, the term “and/or” used in the present disclosure covers any one of the listed items and all possible combinations.

The various components described herein may be referred to as “modules.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, as applicable and relevant, may alternatively be referred to herein as “circuitry,” “controllers,” “processors,” or “processing circuitry,” or alternatively as noted herein.

What is claimed is:

1. A coil assembly, comprising:
a flexible radio frequency (RF) receiving coil element comprising a variable capacitor; and
a tuning controller configured to adjust a capacitance of the variable capacitor of the flexible RF receiving coil element to thereby adjust a resonant frequency of the flexible RF receiving coil element to within a preset resonant frequency range.

2. The coil assembly as claimed in claim 1, wherein:
the tuning controller is further configured to transmit a first signal having a magnetic resonance frequency,
the flexible RF receiving coil element further comprises a directional coupler connected to the tuning controller, the directional coupler configured to transmit the first signal to the flexible RF receiving coil element, and to transmit a second signal, which is returned by the flexible RF receiving coil element after the first signal has passed through the flexible RF receiving coil element, to the tuning controller.

3. The coil assembly as claimed in claim 2, wherein the tuning controller is configured to determine whether to adjust the capacitance of the variable capacitor based upon the second signal being within a preset second signal range.

4. The coil assembly as claimed in claim 1, wherein:
the coil assembly is configured as part of an MRI system, which comprises a body coil and a measurement reconstruction system,
the body coil is configured to transmit a first signal to the flexible RF receiving coil element,
the measurement reconstruction system is configured to receive a second signal from the flexible RF receiving coil element,
the second signal comprises a signal returned after the first signal has passed through the flexible RF receiving coil element, and
the tuning controller is configured to be in communicative connection with the measurement reconstruction system so as to receive the second signal or a control signal transmitted by the measurement reconstruction system that indicates whether to adjust the capacitance of the variable capacitor.

5. The coil assembly as claimed in claim 4, wherein an amplitude of the first signal is selected to be lower than a signal amplitude capable of activating passive detuning of the flexible RF receiving coil.

6. The coil assembly as claimed in claim 1, wherein the variable capacitor comprises a voltage-controlled capacitor, and
wherein the tuning controller is configured to adjust a control voltage applied to the voltage-controlled capacitor.

7. The coil assembly as claimed in claim 1, further comprising:
a fixed capacitor connected in parallel with the variable capacitor.

8. The coil assembly as claimed in claim 2, wherein the tuning controller is configured to:
generate the first signal;
receive the second signal;
generate a control instruction; and
generate a control signal for controlling a voltage of the variable capacitor.

9. The coil assembly as claimed in claim 1, wherein the coil assembly is coupled to a magnetic resonance imaging (MRI) system.

10. A tuning method for a magnetic resonance imaging (MRI) system, comprising:
transmitting a first signal to a flexible radio frequency (RF) receiving coil element that is part of a coil assembly;
receiving a second signal from the flexible RF receiving coil element,
wherein the second signal comprises a signal returned after the first signal has passed through the flexible RF receiving coil element; and
adjusting, via a tuning controller, a capacitance of a variable capacitor of the flexible RF receiving coil element according to the second signal to thereby adjust a resonant frequency of the flexible RF receiving coil element to within a preset resonant frequency range.

11. The tuning method as claimed in claim 10, further comprising:
after the flexible RF receiving coil element has been placed on a test subject and the test subject is at a scanning position, transmitting, via the tuning controller, the first signal to the flexible RF receiving coil element;
receiving, via the tuning controller, the second signal from the flexible RF receiving coil element; and
determining, via the tuning controller, whether to adjust the capacitance of the variable capacitor based upon the second signal being within a preset second signal range.

12. The tuning method as claimed in claim 10, wherein the coil assembly is coupled to the MRI system, which comprises a body coil and a measurement reconstruction system, the body coil being configured to transmit the first signal to the flexible RF receiving coil element, and the measurement reconstruction system being configured to receive the second signal from the flexible RF receiving coil element, and
wherein the method further comprises:
receiving, via the tuning controller, the second signal from the measurement reconstruction system or a control signal transmitted by the measurement reconstruction system based upon the second signal, the control signal indicating whether to adjust the capacitance of the variable capacitor.
